(19) United States
(12) Patent Application Publication
(10) Pub. No.: US 2024/0021766 A1
(43) Pub. Date: Jan. 18, 2024

(54) DISPLAY PANEL AND DISPLAY DEVICE

(71) Applicants: Huizhou China Star Optoelectronics Display Co., Ltd., Huizhou (CN); TCL China Star Optoelectronics Technology Co., Ltd., Shenzhen (CN)

(72) Inventors: Wenbin WANG, Huizhou (CN); Lijian XIAO, Huizhou (CN); Linlin FU, Huizhou (CN); Guanqiao ZHAO, Huizhou (CN)

(73) Assignees: Huizhou China Star Optoelectronics Display Co., Ltd., Huizhou (CN); TCL China Star Optoelectronics Technology Co., Ltd., Shenzhen (CN)

(21) Appl. No.: 17/876,608

(22) Filed: Jul. 29, 2022

(30) Foreign Application Priority Data
Jul. 14, 2022 (CN) 202210834402.6

(51) Int. Cl. H01L 33/62; H01L 25/075

(52) U.S. Cl. CPC H01L 33/62; H01L 25/0753

(57) ABSTRACT

A display panel and a display device are provided. The display panel includes a driving backplate, a plurality of light-emitting diode (LED) chips disposed on a side of the driving backplate, and an adhesive. The adhesive includes a first state and a second state. Viscosity of the adhesive in the second state is less than viscosity of the adhesive in the first state. The driving backplate and the LED chips are fixedly connected to each other by the adhesive in the first state. The adhesive can be converted from the first state into the second state by laser irradiation, and power of the laser is less than 10 w. The driving backplate and the LED chips are attached to each other by the adhesive in the first state, and viscosity of the adhesive in the first state can be reduced by irradiation with a low-power laser.

### RELATED APPLICATION

This application claims the benefit of priority of China Patent Application No. 202210834402.6 filed on Jul. 14, 2022, the contents of which are incorporated by reference as if fully set forth herein in their entirety.

### FIELD

The present disclosure relates to a field of display technologies, and more particularly, to a display panel and a display device.

### BACKGROUND

Nowadays, mini-scale light-emitting diodes (LEDs), such as mini-LEDs and micro-LEDs, become increasingly popular in a display market. However, manufacturing processes of the mini-scale LEDs are difficult because a size of the mini-scale LEDs is small. Thus, a yield rate of the mini-scale LEDs still cannot achieve expectations. In addition, display products of the mini-scale LEDs need to be repaired frequently.

In conventional mini-scale LED display products, an LED chip and a driving backplate are fixedly connected to each other by solder, e.g., solder paste. When defective LED chips are repaired, a high-power laser is used to remove the defective LED chips, and new LED chips are rewelded to correspondingly positions with solder by a high-power laser. During processes of removing and rewelding, LED chips are easy to be damaged by a high-power laser. As such, the LED chips may have a low brightness or fail, which complicates repairing processes and reduces a repairing yield rate and a display quality.

### SUMMARY

The present disclosure provides a display panel and a display device, which can effectively solve following issues: in conventional mini-scale LED display products, repairing processes are complicated, a yield rate is low, and a display quality is poor.

In one aspect, the present disclosure provides a display panel, comprising:
a driving backplate;
a plurality of light-emitting diode (LED) chips disposed on a side of the driving backplate;
an adhesive, wherein the adhesive comprises a first state and a second state, viscosity of the adhesive in the second state is less than viscosity of the adhesive in the first state, and the driving backplate and the LED chips are fixedly connected to each other by the adhesive in the first state;
wherein the adhesive is converted from the first state into the second state by laser irradiation, and power of a laser is less than 10 w.

Optionally, the driving backplate comprises a driving substrate and a plurality of pads disposed on a side of the driving substrate, the LED chips comprise a main LED chip body and a plurality of pins, the pins are disposed on a side of the pads away from the driving substrate, the main LED chip body is disposed on a side of the pins away from the pads, and the pads are directly in contact with the pins.

Optionally, the driving substrate comprises a plurality of recesses, the pads are disposed in the recesses, and the pins are at least partly contained in the recesses.

Optionally, an opening size of the recesses is increasingly increased along a direction from the driving substrate to the main LED chip body, and a cross-section of the recesses is trapezoid.

Optionally, the driving substrate comprises a plurality of protrusions configured to confine and form the recesses, the main LED chip body is disposed outside the recesses, and the adhesive in the first state is disposed on a side of the protrusions toward the main LED chip body or is disposed in the recesses.

Optionally, the pins at least partly protrude from the recesses, the display panel comprises an encapsulation adhesive disposed on a same layer as the main LED chip body, and the adhesive in the first state is disposed between the encapsulation adhesive, the main LED chip body, and the protrusions.

Optionally, the recesses comprise a bottom wall and a lateral wall, and the pads comprise a first part disposed between the bottom wall and the pins and a second part disposed between the lateral wall and the pins.

Optionally, the adhesive in the first state is disposed between the lateral wall and the pins, the lateral wall comprises a first area and a second area outside the first area, the second part of the pads is disposed on the first area, and the adhesive in the first state disposed between the lateral wall and the pins is disposed on the second area.

Optionally, the adhesive is converted from the second state into the first state by laser irradiation, and power of a laser is less than 10 w.

Optionally, a wavelength of the laser is greater than 900 nm, the adhesive is converted from the second state into the first state by laser irradiation at temperatures ranging from 100 □ to 110 □, and the adhesive is converted from the second state into the first state by laser irradiation at temperatures ranging from 140 □ to 150 □.

Optionally, both the adhesive in the first state and the adhesive in the second state are insulated.

In another aspect, the present disclosure provides a display device, comprising a case and a display panel, wherein the case comprises a containing space, and the display panel is disposed in the containing space;
wherein the display panel comprises:
a driving backplate;
a plurality of light-emitting diode (LED) chips disposed on a side of the driving backplate;
an adhesive, wherein the adhesive comprises a first state and a second state, viscosity of the adhesive in the second state is less than viscosity of the adhesive in the first state, and the driving backplate and the LED chips are fixedly connected to each other by the adhesive in the first state; and
wherein the adhesive is converted from the first state into the second state by laser irradiation, and power of a laser is less than 10 w.

Optionally, the driving backplate comprises a driving substrate and a plurality of pads disposed on a side of the driving substrate, the LED chips comprise a main LED chip body and a plurality of pins, the pins are disposed on a side of the pads away from the driving substrate, the main LED chip body is disposed on a side of the pins away from the pads, and the pads are directly in contact with the pins.

Optionally, the driving substrate comprises a plurality of recesses, the pads are disposed in the recesses, and the pins are at least partly contained in the recesses.

Optionally, an opening size of the recesses is increasingly increased along a direction from the driving substrate to the main LED chip body, and a cross-section of the recesses is trapezoid.

Optionally, the driving substrate comprises a plurality of protrusions configured to confine and form the recesses, the main LED chip body is disposed outside the recesses, and the adhesive in the first state is disposed on a side of the protrusions toward the main LED chip body or is disposed in the recesses.

Optionally, the pins at least partly protrude from the recesses, the display panel comprises an encapsulation adhesive disposed on a same layer as the main LED chip body, and the adhesive in the first state is disposed between the encapsulation adhesive, the main LED chip body, and the protrusions.

Optionally, the recesses comprise a bottom wall and a lateral wall, and the pads comprise a first part disposed between the bottom wall and the pins and a second part disposed between the lateral wall and the pins.

Optionally, the adhesive in the first state is disposed between the lateral wall and the pins, the lateral wall comprises a first area and a second area outside the first area, the second part of the pads is disposed on the first area, and the adhesive in the first state disposed between the lateral wall and the pins is disposed on the second area.

Optionally, the adhesive is converted from the second state into the first state by laser irradiation, and power of a laser is less than 10 w.

Optionally, a wavelength of the laser is greater than 900 nm, the adhesive is converted from the second state into the first state by laser irradiation at temperatures ranging from 100 □ to 110 □, and the adhesive is converted from the second state into the first state by laser irradiation at temperatures ranging from 140 □ to 150 □.

The present disclosure provides a display panel and a display device. A driving backplate and an LED chip are attached to each other by an adhesive in a first state. Viscosity of the adhesive in the first state can be reduced by irradiation with a low-power laser, which makes the LED chip easy to be repaired without damaging the LED chip. Therefore, a repairing yield rate is increased, and a display quality of the display panel is improved.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic plan view showing an LED chip disposed on a driving backplate provided by an embodiment of the present disclosure.

FIG. 2 is a schematic cross-sectional view of FIG. 1 taken along line AA.

FIG. 3 is another schematic cross-sectional view of FIG. 1 taken along line AA.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure. It should be noted that described embodiments are merely used to construct the present disclosure and are not intended to limit the present disclosure. In the present disclosure, unless further description is made, terms such as “top” and “bottom” usually refer to a top of a device and a bottom of a device in an actual process or working status, and specifically, to the orientation as shown in the drawings. Terms such as “inside” and “outside” are based on an outline of a device.

The disclosure below provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art. It should be noted that the description order of embodiments does not limit preferred orders of the embodiments.

### First Embodiment

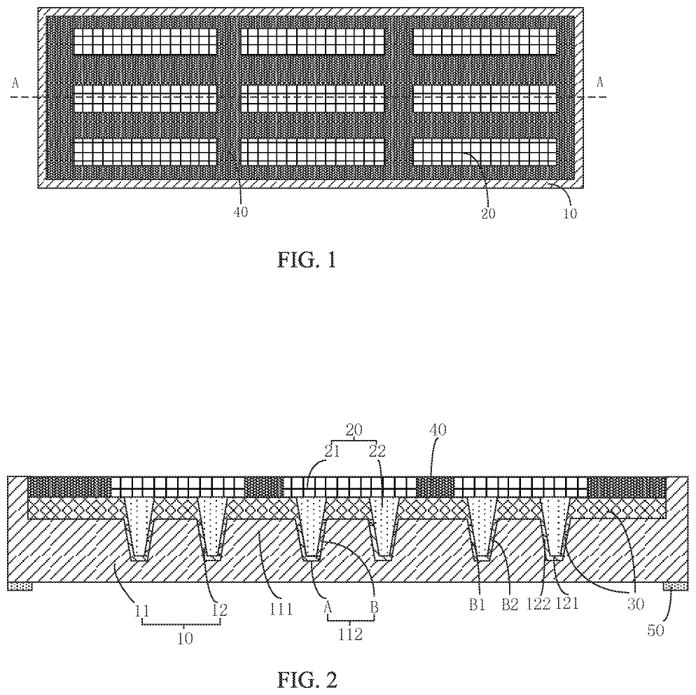

FIG. 1 is a schematic plan view showing an LED chip disposed on a driving backplate provided by an embodiment of the present disclosure. FIG. 2 is a schematic cross-sectional view of FIG. 1 taken along line AA. As shown in FIG. 1 and FIG. 2, a display panel includes a driving backplate 10, a plurality of LED chips 20 disposed on a side of the driving backplate 10, and an adhesive 30. The adhesive 30 includes a first state and a second state. Viscosity of the adhesive in the second state is less than viscosity of the adhesive in the first state. The driving backplate 10 and the LED chips 20 are fixedly connected to each other by the adhesive 30 in the first state. The adhesive 30 can be converted from the first state into the second state by laser irradiation, and power of a laser is less than 10 w.

In the present disclosure, the driving backplate and the LED chips are attached to each other by the adhesive in the first state. Viscosity of the adhesive in the first state can be reduced by irradiation with a lower-power laser, which makes the LED chips easy to be repaired without damaging the LED chips. Therefore, a repairing yield rate and a display quality of the display panel are improved.

Furthermore, the driving backplate 10 includes a driving substrate 11 and a plurality of pads 12 disposed on a side of the driving substrate 11. The LED chips 20 include a main LED chip body 21 and a plurality of pins 22. The main LED chip body 21 is disposed on a side of the pins 22 away from the pads. The pads 12 are directly in contact with the pins 22. The adhesive 30 in the first state is configured to make the pads 12 and the pins 22 attached to each other, thereby ensuring stability of electrical connection between the pads 12 and the pins 22.

In the display panel provided by the present disclosure, since the pads 12 and the pins 22 are directly in contact with each other, it is not necessary to dispose solder, which adapts to a high-power laser, between the pads 12 and the pins 22 for repairing processes.

In addition, in the present disclosure, the pads 12 and the pins 22 are attached to each other by the adhesive 30 in the first state. Since viscosity of the adhesive 30 in the first state can be reduced by irradiation with a low-power laser, the LED chips 20 can be easily repaired without damaging the LED chips 20. As such, a repairing yield rate is improved. An issue of LED chips 20 having a low brightness or being unable to emit light normally is prevented, thereby improving a display quality of the display panel and a display quality of a display device.

Furthermore, minimum viscosity of the adhesive 30 in the second state can be 0.

In some embodiments of the present disclosure, the driving substrate 11 includes a plurality of protrusions 111 and a plurality of recesses 112 confined by the protrusions 111. The pads 12 are disposed in the recesses 112. The pins 22 are at least partly contained in the recesses 112.

In the present disclosure, the recesses 112 are formed on the driving substrate 11, and the pads 12 and the pins 22 are at least partly disposed in the recesses 112. Therefore, during assembly processes of the LED chips 20, the pads 12 and the pins 22 can correspond to each other precisely. The pads 12 and the pins 22 can be attached to each other more firmly, thereby preventing dislocation between the pads 12 and the pins 22. Thus, stability of electrical connection between the pads 12 and the pins 22 is improved.

Preferably, an opening size of the recesses is increasingly increased along a direction from the driving substrate 11 to the main LED chip body 21. Along a direction perpendicular to the driving substrate 11, a cross-section of the recesses 112 is trapezoid, which further reduces a difficulty in corresponding the pins 22 to the recesses 112. Therefore, the pads 12 and the pins 22 are easier to correspond to each other.

In some embodiments of the present disclosure, the main LED chip body 21 is disposed outside the recesses 112. The adhesive 30 in the first state is disposed on a side of the protrusions 111 toward the main LED chip body 21, and/or is disposed in the recesses 112.

Specifically, the adhesive 30 in the first state is disposed on the side of the protrusions 111 toward the main LED chip body 21 and is disposed in the recesses 112. The main LED chip body 21 disposed outside the recesses 112 is fixedly connected to the driving substrate 11 by the adhesive 30 in the first state disposed on the side of the protrusions 111 toward the main LED chip body 21. The main LED chip body 21 disposed in the recesses 112 is fixedly connected to the pins 22 by the adhesive 30 in the first state disposed in the recesses 112.

Since the adhesive 30 in the first state is disposed on the side of the protrusions 111 toward the main LED chip body 21 and is disposed in the recesses 112, an adhesive area of the adhesive 30 in the first state is significantly increased. Therefore, the driving substrate 10 and the LED chips 20 are integratedly connected to each other, which not only makes the pads 12 and the pins 22 directly in contact with each other but also significantly reduces risks of dislocation between the pads 12 and the pins 22. As such, stability of electrical connection between the pads 12 and the pins 22 is improved.

In some embodiments of the present disclosure, the pins 22 at least partly protrude from the recesses 112. The display panel further includes an encapsulation adhesive 40 disposed on a same layer as the main LED chip body 21. The adhesive 30 in the first state is disposed between the encapsulation adhesive 40, the main LED chip body 21, and the protrusions 111.

Specifically, since the pins 22 at least partly protrude from the recesses, a gap area is generated between the encapsulation adhesive 40, the main LED chip body 21, and the protrusions 111, which provides space for disposing adhesive 30 in the first state between the encapsulation adhesive 40, the main LED chip body 21, and the protrusions 111.

Furthermore, the encapsulation adhesive layer 40 is configured to encapsulate the driving backplate 10 and the LED chips 20, thereby improving encapsulation performance of the display panel and working stability of the LED chips 20. The adhesive 30 in the first state is disposed between the encapsulation adhesive 40, the main LED chip body 21, and the protrusions 111. That is, the encapsulation adhesive 40 can be isolated from the protrusions 111 by the adhesive 30 in the first state. During manufacturing processes of the display panel, the adhesive 30 is converted from the first state to the second state by laser irradiation. When the LED chips 20 are disassembled or replaced, the adhesive 30 in the second state disposed between the encapsulation adhesive 40, the main LED chip body 21, and the protrusions 111 can prevent the encapsulation adhesive 40 and the protrusions 111 from direct contact. Therefore, an issue of increased repairing difficulty due to the encapsulation adhesive 40 and the protrusions 111 attached to each other is prevented.

In some embodiments of the present disclosure, the recesses 112 include a bottom wall A and a lateral wall B. The pads 12 include a first part 121 disposed between the bottom wall A and the pins 22 and a second part 122 disposed between the lateral B and the pins 22.

Specifically, the pads 12 and a driving circuit of the driving substrate 11 are electrically connected to each other. Since the pads 12 include not only the first part 121 disposed on the bottom wall A but also the second part 122 disposed on the lateral wall B, an area of the pads 12 can be greater. Therefore, stability of electrical connection between the pads 12, the driving circuit, and the pins 22 can be further ensured, and working stability of the display panel can be further improved.

In some embodiments of the present disclosure, the adhesive 30 in the first state is further disposed between the lateral wall B and the pins 22. The lateral wall B includes a first area B1 and a second area B2 outside the first area B1. The second part 122 of the pads 12 is disposed on the first area B1, and the adhesive 30 in the first state is disposed on the second area B2.

Specifically, the first area B1 includes the second part 122 defined on the pads 12 in the recesses, and the second area B2 includes the adhesive 30 in the first state disposed in the recesses 112. That is, in the recesses 112, the pads 12 and the adhesive 30 in the first state respectively correspond to different positions on the lateral wall B. thereby ensuring that the pads 12 and the pins 22 can be directly and electrically connected to each other and can precisely correspond to each other.

In some embodiments of the present disclosure, the adhesive 30 can be converted from the second state into the first state by laser irradiation, and power of a laser is less than 10 W.

Specifically, since the adhesive 30 can be converted from the first state having relatively high viscosity into the second state having relatively low viscosity by irradiation with a low-power laser, a disassembly yield rate and disassembly efficiency of the LED chips 20 can be significantly improved. Moreover, the adhesive 30 can be further converted from the second state having relatively low viscosity into the first state having relatively high viscosity by irradiation with a low-power laser. Therefore, an assembly yield rate and assembly efficiency of the LED chips 20 can be significantly improved.

Furthermore, disassembly processes and assembly processes of the LED chips 20 can be performed by using a same laser device in a same processing chamber. Therefore, repairing cost of the LED chips 20 can be significantly reduced.

In some embodiments of the present disclosure, a wavelength of a laser is greater than 900 nm. For example, the wavelength of the laser is 981 nm. Since the wavelength of the laser is relatively great, power of the laser is relatively low. Therefore, a repairing yield rate of can be improved, damage of the LED chips 20 can be reduced, and a display effect of the display panel can be ensured.

In some embodiments of the present disclosure, within temperatures ranging from 100 □ to 110 □, the adhesive 30 can be converted from the second state into the first state by laser irradiation. Within temperatures ranging from 140 □ to 150 □, the adhesive 30 can be converted from the second state to the first state.

It should be noted that when the adhesive 30 is converted from the first state having high viscosity into the second state having low viscosity, the adhesive 30 still can be restored to the first state having high viscosity by laser irradiation.

Furthermore, both the adhesive 30 in the first state and the adhesive 30 in the second state are insulated. That is, the adhesive 30 is not conductive. Therefore, the adhesive 30 is not disposed between the pads 12 and the pins 22, thereby ensuring that the pads 12 and the pins 22 can directly in contact with each other. Thus, electrical connection performance can be ensured.

In some embodiments of the present disclosure, the display panel further includes a driving chip 50 disposed on a side of the driving backplate 10 away from the LED chips 20. The driving chip 50 is configured to control the driving circuit of the driving substrate 11.

In some embodiments of the present disclosure, the main LED chip body 21 includes an LED unit.

The LED unit can be directly used as a pixel unit of the display panel. That is, the display panel is a direct view display panel.

Alternatively, the LED unit may be used as a backlight source of the display panel. Correspondingly, the display panel further includes a main display panel body. The main display panel body is disposed on a side of the main LED chip body 21 away from the driving backplate 10. The main display panel body includes two substrates opposite to each other and a liquid crystal layer disposed between the two opposite substrates. That is, the display panel may also be a liquid crystal display panel.

In another aspect, the present disclosure further provides a display device. The display device includes a case and any one of the above display panels. The case includes a containing space, and the display panel is disposed in the containing space.

### Second Embodiment

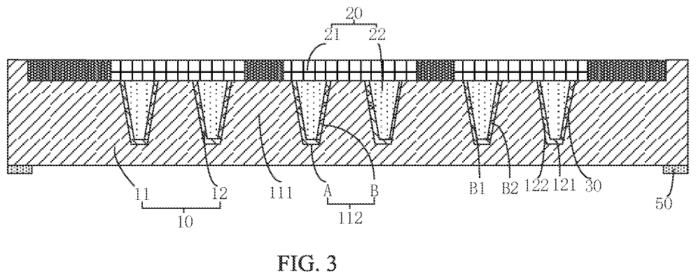

FIG. 3 is another schematic cross-sectional view of FIG. 1 taken along line AA. As shown in FIG. 1 and FIG. 3, the second embodiment of the present disclosure provides a display panel. The display panel includes a driving backplate 10, a plurality of LED chips 20 disposed on a side of the driving backplate 10, and an adhesive 30. The adhesive 30 includes a first state and a second state. Viscosity of the adhesive in the second state is less than viscosity of the adhesive in the first state. The driving backplate 10 and the LED chips 20 are fixedly connected to each other by the adhesive 30 in the first state. The adhesive 30 can be converted from the first state into the second state by laser irradiation, and power of a laser is less than 10 w.

The display panel provided by the second embodiment and the display panel provided by the first embodiment have a similar structure. Same parts of the first embodiment and the second embodiment are not described here again.

Differences between the first embodiment and the second embodiment are: in the second embodiment, the driving substrate 11 includes a plurality of protrusions 111 and a plurality of recesses 112 confined by the protrusions 111. A plurality of pads 12 are disposed in the recesses 112. A plurality of pins 22 are contained in the recesses 112.

In the present disclosure, the recesses 112 are formed on the driving substrate 11, and the pads 12 and the pins 22 are at least partly disposed in the recesses 112. Therefore, during assembly processes of the LED chips 20, the pads 12 and the pins 22 can correspond to each other precisely by the recesses 112. In addition, the pins 22 are contained in the recesses 112, thereby making the pads 12 and the pins 22 better correspond to each other. Thus, dislocation between the pads 12 and the pins 22 can be prevented, and stability of electrical connection between pads 12 and the pins 22 can be improved.

Furthermore, the main LED chip body 21 is disposed outside the recesses 112. The adhesive 30 in the first state is disposed in the recesses 112. The display panel further includes an encapsulation layer 40 disposed on a same layer as the main LED chip body 21. The encapsulation adhesive 40, the main LED chip body 21, and the protrusions 111 are directly in contact with each other.

In the display panel provided by the present disclosure, the encapsulation adhesive 40, the main LED chip body 21, and the protrusions 111 are directly in contact with each other, and the adhesive 30 in the first state is only disposed in the recesses 112. Therefore, compared with the first embodiment, in the second embodiment, the adhesive 30 in the first state disposed between the encapsulation adhesive 40, the main LED chip body 21, and the protrusions 111 can be omitted. Therefore, a layer structure of the display panel is simplified, so that the display panel can be lighter and thinner.

In another aspect, the present disclosure further provides a display device. The display device includes a case and any one of the above display panels. The case includes a containing space, and the display panel is disposed in the containing space.

In summary, the present disclosure provides a display panel and a display device. The display panel includes a driving backplate, a plurality of LED chips disposed on a side of the driving backplate, and an adhesive. The adhesive includes a first state and a second state. Viscosity of the adhesive in the second state is less than viscosity of the adhesive in the first state. The driving backplate and the LED chips are fixedly connected to each other by the adhesive in the first state. The adhesive can be converted from the first state into the second state by laser irradiation, and power of a laser is less than 10 w. In the present disclosure, the driving backplate and the LED chips are attached to each other by the adhesive in the first state. Therefore, the LED chips are easier to be repaired without damaging the LED chips. Thus, a repairing yield rate is improved.

A display panel and a display device have been described in detail by the above embodiments, which illustrates principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A display panel, comprising:
a driving backplate;
a plurality of light-emitting diode (LED) chips disposed on a side of the driving backplate;
an adhesive, wherein the adhesive comprises a first state and a second state, viscosity of the adhesive in the second state is less than viscosity of the adhesive in the first state, and the driving backplate and the LED chips are fixedly connected to each other by the adhesive in the first state;
wherein the adhesive is converted from the first state into the second state by laser irradiation, and power of a laser is less than 10 w.

2. The display panel of claim 1, wherein the driving backplate comprises a driving substrate and a plurality of pads disposed on a side of the driving substrate, the LED chips comprise a main LED chip body and a plurality of pins, the pins are disposed on a side of the pads away from the driving substrate, the main LED chip body is disposed on a side of the pins away from the pads, and the pads are directly in contact with the pins.

3. The display panel of claim 2, wherein the driving substrate comprises a plurality of recesses, the pads are disposed in the recesses, and the pins are at least partly contained in the recesses.

4. The display panel of claim 3, wherein an opening size of the recesses is increasingly increased along a direction from the driving substrate to the main LED chip body, and a cross-section of the recesses is trapezoid.

5. The display panel of claim 3, wherein the driving substrate comprises a plurality of protrusions configured to confine and form the recesses, the main LED chip body is disposed outside the recesses, and the adhesive in the first state is disposed on a side of the protrusions toward the main LED chip body or is disposed in the recesses.

6. The display panel of claim 5, wherein the pins at least partly protrude from the recesses, the display panel comprises an encapsulation adhesive disposed on a same layer as the main LED chip body, and the adhesive in the first state is disposed between the encapsulation adhesive, the main LED chip body, and the protrusions.

7. The display panel of claim 5, wherein the recesses comprise a bottom wall and a lateral wall, and the pads comprise a first part disposed between the bottom wall and the pins and a second part disposed between the lateral wall and the pins.

8. The display panel of claim 7, wherein the adhesive in the first state is disposed between the lateral wall and the pins, the lateral wall comprises a first area and a second area outside the first area, the second part of the pads is disposed on the first area, and the adhesive in the first state disposed between the lateral wall and the pins is disposed on the second area.

9. The display panel of claim 1, wherein the adhesive is converted from the second state into the first state by laser irradiation, and power of a laser is less than 10 w.

10. The display panel of claim 9, wherein a wavelength of the laser is greater than 900 nm, the adhesive is converted from the second state into the first state by laser irradiation at temperatures ranging from 100 □ to 110 □, and the adhesive is converted from the second state into the first state by laser irradiation at temperatures ranging from 140 □ to 150 □.

11. A display device, comprising a case and a display panel, wherein the case comprises a containing space, and the display panel is disposed in the containing space;
wherein the display panel comprises:
a driving backplate;
a plurality of light-emitting diode (LED) chips disposed on a side of the driving backplate;
an adhesive, wherein the adhesive comprises a first state and a second state, viscosity of the adhesive in the second state is less than viscosity of the adhesive in the first state, and the driving backplate and the LED chips are fixedly connected to each other by the adhesive in the first state; and
wherein the adhesive is converted from the first state into the second state by laser irradiation, and power of a laser is less than 10 w.

12. The display device of claim 11, wherein the driving backplate comprises a driving substrate and a plurality of pads disposed on a side of the driving substrate, the LED chips comprise a main LED chip body and a plurality of pins, the pins are disposed on a side of the pads away from the driving substrate, the main LED chip body is disposed on a side of the pins away from the pads, and the pads are directly in contact with the pins.

13. The display device of claim 12, wherein the driving substrate comprises a plurality of recesses, the pads are disposed in the recesses, and the pins are at least partly contained in the recesses.

14. The display device of claim 13, wherein an opening size of the recesses is increasingly increased along a direction from the driving substrate to the main LED chip body, and a cross-section of the recesses is trapezoid.

15. The display device of claim 13, wherein the driving substrate comprises a plurality of protrusions configured to confine and form the recesses, the main LED chip body is disposed outside the recesses, and the adhesive in the first state is disposed on a side of the protrusions toward the main LED chip body or is disposed in the recesses.

16. The display device of claim 15, wherein the pins at least partly protrude from the recesses, the display panel comprises an encapsulation adhesive disposed on a same layer as the main LED chip body, and the adhesive in the first state is disposed between the encapsulation adhesive, the main LED chip body, and the protrusions.

17. The display device of claim 15, wherein the recesses comprise a bottom wall and a lateral wall, and the pads comprise a first part disposed between the bottom wall and the pins and a second part disposed between the lateral wall and the pins.

18. The display device of claim 17, wherein the adhesive in the first state is disposed between the lateral wall and the pins, the lateral wall comprises a first area and a second area outside the first area, the second part of the pads is disposed on the first area, and the adhesive in the first state disposed between the lateral wall and the pins is disposed on the second area.

19. The display device of claim 11, wherein the adhesive is converted from the second state into the first state by laser irradiation, and power of a laser is less than 10 w.

20. The display device of claim 19, wherein a wavelength of the laser is greater than 900 nm, the adhesive is converted from the second state into the first state by laser irradiation at temperatures ranging from 100 □ to 110 □, and the adhesive is converted from the second state into the first state by laser irradiation at temperatures ranging from 140 □ to 150 □.
